(19) United States
(12) Patent Application Publication
(10) Pub. No.: US 2026/0096458 A1
(43) Pub. Date: Apr. 2, 2026

(54) SEMICONDUCTOR PACKAGE

(71) Applicant: NEPES CO., LTD., Chungcheongbuk-do (KR)

(72) Inventors: Jueok Park, Chungcheongbuk-do (KR); Sunghyuk Lee, Chungcheongbuk-do (KR); Hanju Yu, Chungcheongbuk-do (KR); Jungwon Lee, Chungcheongbuk-do (KR); Insoo Kang, Chungcheongbuk-do (KR)

(21) Appl. No.: 19/347,613

(22) Filed: Oct. 1, 2025

(30) Foreign Application Priority Data
Oct. 2, 2024 (KR) 10-2022-0182280

(51) Int. Cl. H01L 23/538; H01L 23/00; H01L 23/28; H01L 23/498; H01L 25/07

(52) U.S. Cl. CPC H10W 70/65; H10W 70/611; H10W 70/685; H10W 74/00; H10W 90/701; H10W 90/00; H10W 90/724

(57) ABSTRACT

A semiconductor package according to an embodiments includes a bridge chip including a connection pad; a redistribution structure disposed on the bridge chip and including a redistribution line connected to the connection pad of the bridge chip; and a first semiconductor chip and a second semiconductor chip disposed on the redistribution structure and spaced apart from each other along a horizontal direction and including a terminal pad connected to the redistribution line, wherein one of the connection pad and the terminal pad is positioned on a same plane as the redistribution structure, other pad of the connection pad and the terminal pad is positioned on a different plane from the redistribution structure, and a first conductive bump is disposed between the other pad and the redistribution structure.

### CROSS-REFERENCE TO RELATED APPLICATIONS

This application is based on and claims priority under 35 U.S. C. § 119 to Korean Patent Application No. 10-2022-0182280, filed on Oct. 2, 2024, in the Korean Intellectual Property Office, the disclosures of which are incorporated by reference herein in their entirety.

### BACKGROUND

### Field

An embodiment relates to a semiconductor package.

### Description of the Related Art

A number of input/output (I/O) terminals required for a semiconductor is increasing due to the increasing performance of various mobile devices. Accordingly, wafer-level packaging (WLP) technology, which performs semiconductor packaging processes at a wafer level and separates wafer level semiconductor packages into individual units after the semiconductor packaging processes, is attracting attention.

Fan-Out Wafer Level Package (FOWLP) or Fan-Out Panel Level Package (FOPLP) is a technology that directly mounts semiconductor chips on a wafer rather than on a circuit board (e.g., PCB). In the case of semiconductor packages manufactured by FOWLP and/or FOPLP, a manufacturing cost of semiconductor packages can be lowered as circuit boards are not used, and semiconductor packages can be miniaturized, heat dissipation functions can be improved, power consumption can be reduced, and frequency band can be improved.

FOWLP or FOPLP is manufactured by attaching individual dies to a carrier, molding the individual dies with a molding member, and then performing a process of forming a fan-out type redistribution layer (RDL) and a bumping process.

In this case, the process of manufacturing a semiconductor package according to FOWLP or FOPLP, as described above, can be performed by stacking different materials along a vertical direction. For example, a redistribution insulating layer of a redistribution structure may include an organic material, the die may include silicon, and a molding material may include an epoxy mold compound (EMC). These materials may have different properties (e.g., coefficients of thermal expansion). Furthermore, each of the materials undergoes a curing process after stacking. This curing process can cause warping of the semiconductor package. For example, semiconductor packages can experience upward convex warpage (crying warpage) or downward concave warpage (smile warpage) during the manufacturing process due to differences in coefficients of thermal expansion between the materials, as described above, and/or contraction or expansion during the curing process.

Furthermore, if such warpage occurs, processability in a process of forming the redistribution structure can be deteriorated, thus a manufacturing process may be complicated and product yield may be deteriorated. Furthermore, at least one of a plurality of terminals provided in the die may cause an electrical reliability problem that is not electrically connected to the redistribution layer due to the warpage as described above, and thus product reliability may be greatly deteriorated. Accordingly, there is a need for a technology capable of improving product reliability by simplifying a conventional process of FOWLP and FOPLP and improving process efficiency.

### SUMMARY

An embodiment provides a semiconductor package capable of preventing the warpage occurring during a manufacturing process and a manufacturing method the same.

In addition, the embodiment provides a method of manufacturing a semiconductor package that may achieve product yield improvement by solving process complexity.

In addition, the embodiment provides a semiconductor package capable of preventing the underfill member from spreading and a manufacturing method the same.

Technical problems to be solved by the proposed embodiments are not limited to the above-mentioned technical problems, and other technical problems not mentioned may be clearly understood by those skilled in the art to which the embodiments proposed from the following descriptions belong.

A semiconductor package according to an embodiment comprises a bridge chip including a connection pad; a redistribution structure disposed on the bridge chip and including a redistribution line connected to the connection pad of the bridge chip; and first semiconductor chip and a second semiconductor chip disposed on the redistribution structure and spaced apart from each other along a horizontal direction and including a terminal pad connected to the redistribution line, herein one of the connection pad and the terminal pad is positioned on a same plane as the redistribution structure, wherein other pad of the connection pad and the terminal pad is positioned on a different plane from the redistribution structure, and wherein a first conductive bump is disposed between the other pad and the redistribution structure.

In addition, the semiconductor package further comprises a first molding member molding the first semiconductor chip and the second semiconductor chip; a second molding member molding the bridge chip; and a vertical connection conductor passing through the second molding member along a vertical direction, wherein the redistribution line of the redistribution structure includes a plurality of redistribution patterns disposed at different vertical levels, and a plurality of redistribution vias disposed between the plurality of redistribution patterns and disposed at different vertical levels, wherein the terminal pad is in direct contact with a redistribution via that is most closely disposed among the plurality of redistribution vias, and wherein a width of each of the plurality of redistribution vias in a horizonal direction increases from the first semiconductor chip or the second semiconductor chip toward the bridge chip.

In addition, the vertical connection conductor is in direct contact with the redistribution line of the redistribution structure and is electrically connected to the redistribution line, and at least a portion of the vertical connection conductor overlaps the first conductive bump along the horizontal direction.

In addition, the semiconductor package further comprises a circuit board including an upper pad and a lower pad; a second conductive bump disposed between the upper pad of the circuit board and the vertical connection conductor; and a first underfill member disposed on the circuit board and surrounding the second conductive bump.

In addition, the circuit board further includes a first dam part disposed to surround the upper pad, and the first dam part includes a first portion disposed to surround the upper pad, and a second portion spaced from the first portion and surrounding the first portion.

In addition, a width in the horizontal direction or a thickness in the vertical direction of the first portion of the first dam part is different from at least one of a width in the horizontal direction or a thickness in the vertical direction of the second portion of the first dam part.

In addition, the first conductive bump includes: a first bump disposed between the connection pad and the redistribution structure; and a second bump disposed between the vertical connection conductor and the redistribution structure, wherein a second underfill member is further disposed on the second molding member and surrounds the first bump and the second bump.

In addition, the semiconductor package further comprises a second dam part disposed on an upper surface of the second molding member and surrounding the first conductive bump.

In addition, the semiconductor package further comprises a second dam part disposed on a lower surface of the redistribution structure and surrounding the first conductive bump.

In addition, the second underfill member entirely covers an upper surface of the first molding member, a lower surface of the first molding member, and a side surface of the first molding member.

In addition, the second underfill member includes a first region whose width in the horizontal direction decreases and a second region whose width in the horizontal direction increases along a vertical direction from the first molding member toward the second molding member.

In addition, the semiconductor package further comprises a first molding member for molding the first semiconductor chip and the second semiconductor chip; a second molding member for molding the bridge chip; and a vertical connection conductor passing through the second molding member along a vertical direction, wherein the redistribution line of the redistribution structure includes a plurality of redistribution patterns disposed at different vertical levels, and a plurality of redistribution vias disposed between the plurality of redistribution patterns and disposed at different vertical levels, the connection pad is in direct contact with a redistribution via that is most closely disposed among the plurality of redistribution vias, a width of each of the plurality of redistribution vias in a horizontal direction decrease from the first semiconductor chip or the second semiconductor chip toward the bridge chip, a width of the first molding member in the horizontal direction is greater than a width of each of the redistribution structure and the second molding member in the horizontal direction, and an underfill member is disposed to entirely surround a lower surface of the first molding member, an upper surface of the redistribution structure, a side surface of the redistribution structure, a side surface of the second molding member, and a lower surface of the second molding member.

### Advantageous Effects

A semiconductor package of an embodiment may include a redistribution structure, a semiconductor chip, and a bridge chip. The semiconductor chip may be disposed on the redistribution structure, and the bridge chip may be disposed below the redistribution structure. The semiconductor chip and the bridge chip may be respectively bonded to upper and lower portions of the redistribution structure using different bonding methods.

That is, a terminal pad of the semiconductor chip may be directly connected to a redistribution via disposed at an uppermost portion of the redistribution structure. The bridge chip may be electrically connected to a redistribution line of the redistribution structure through a conductive bump, which serves as a bonding member.

Through this, the embodiment may prevent warpage occurring during a process of manufacturing the semiconductor package. Accordingly, the embodiment may improve the manufacturing processability of the semiconductor package, thereby improving the product yield. In other words, the embodiment may improve the reliability of an electrical connection between the semiconductor chip and the redistribution structure and the reliability of the electrical connection between the bridge chip and the redistribution structure, which occur during a process of manufacturing the semiconductor package. Furthermore, the embodiment may solve the complexity of the manufacturing process of the semiconductor package, thereby simplifying the manufacturing process and lowering the process difficulty. The reason why such an effect may be achieved will be described in more detail below.

Specifically, a number of semiconductor chips may be greater than a number of bridge chips. Alternatively, a planar area of the semiconductor chip may be greater than a planar area of the bridge chip. Alternatively, a thickness of the semiconductor chip may be greater than a thickness of the bridge chip. Therefore, when the semiconductor chips are preferentially disposed during a redistribution process in the semiconductor package manufacturing process, warpage can be improved compared to when the bridge chips are preferentially disposed during the redistribution process. For example, the semiconductor chips may function as reinforcing members during the redistribution process, thereby improving rigidity and process characteristics of the redistribution process. Therefore, the embodiment can allow the redistribution structure to be more stably disposed on the semiconductor chips, thereby further improving the electrical and/or physical reliability of the semiconductor package.

Furthermore, a number of terminal pads provided in the semiconductor chip is smaller than a number of connection pads provided in the bridge chip. For example, the number of terminal pads provided in the semiconductor chip is more than 10 times greater than the number of connection pads provided in the bridge chip. Accordingly, when the terminal pad of the semiconductor chip and the redistribution structure are boded using a conductive bump, considerable high-spec equipment is required for alignment between the conductive bump and the terminal pad, and the product yield may be deteriorated due to the high process difficulty.

Unlike this, in an embodiment, when a redistribution process is performed to form a redistribution structure on the terminal pad of the semiconductor chip, the process difficulty is lower than that of a flip chip process using conductive lumps, and the product yield can be improved by simplifying the manufacturing process accordingly. Furthermore, the embodiment allows a bridge chip with a relatively small number of pads to be bonded to the redistribution structure through a flip-chip bonding process. Furthermore, the embodiment allows the redistribution process to be performed on a semiconductor chip with a relatively large number of pads. Therefore, the embodiment can improve the processability in the flip-chip bonding process, thereby simplifying the manufacturing process, and further improving product yield.

Furthermore, the embodiment can further include a dam part provided in at least one of a redistribution structure, a first molding member, a second molding member, and a circuit board. The dam part can be provided in a region where a underfill member is to be disposed. Therefore, the embodiment can control a degree of spreading of the underfill member using the dam part, thereby ensuring that the underfill member is stably disposed only in a designated region. Accordingly, the embodiment can more stably protect the semiconductor package, thereby further improving physical and/or electrical reliability. Furthermore, the embodiment can control the degree of spreading of the underfill member in a horizontal direction, thereby forming a stable underfill member even with a small amount. Therefore, the embodiment can reduce the manufacturing cost of the semiconductor package.

### BRIEF DESCRIPTION OF THE DRAWINGS

FIG. 1 is a cross-sectional view illustrating a semiconductor package according to a first embodiment.

FIG. 2a is a plan view illustrating one example of a terminal pad of the semiconductor chip and a connection pad of a bridge chip of FIG. 1.

FIG. 2b is a plan view illustrating another example of a terminal pad of the semiconductor chip of FIG. 1.

FIG. 3 is a cross-sectional view illustrating a semiconductor package according to a second embodiment.

FIG. 4a to 4i are cross-sectional views illustrating a method of manufacturing the semiconductor package illustrated in FIG. 3 in order of processes.

FIG. 5 is a cross-sectional view illustrating a semiconductor package according to a third embodiment.

FIG. 6a to 6e are cross-sectional views illustrating a method of manufacturing the semiconductor package illustrated in FIG. 5 in order of processes.

FIG. 7 is a cross-sectional view illustrating a semiconductor package according to a fourth embodiment.

FIG. 8 is a cross-sectional view illustrating a semiconductor package according to a fifth embodiment.

FIG. 9 is a cross-sectional view illustrating a semiconductor package according to a sixth embodiment.

FIG. 10 is a top view of the circuit board of FIG. 9.

FIG. 11 is a cross-sectional view illustrating a semiconductor package according to a seventh embodiment.

FIG. 12 is a cross-sectional view illustrating a semiconductor package according to an eighth embodiment.

### DETAILED DESCRIPTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted”by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, preferred embodiments of the present invention will be described in detail with reference to accompanying drawings.

A semiconductor package 100 according to various embodiments of the present invention may be a wafer level package (WLP), a fan-out wafer level package (FOWLP), or a panel level package (PLP), but is not limited thereto.

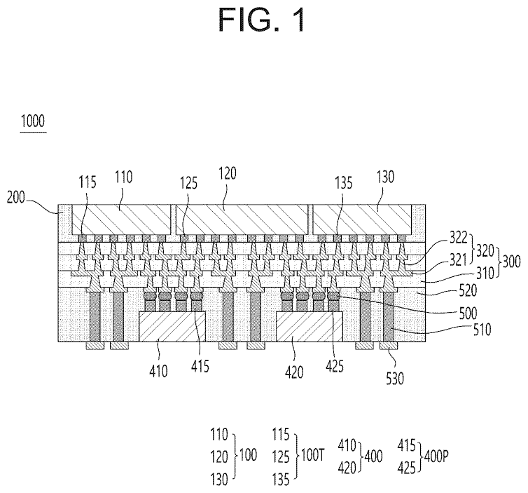

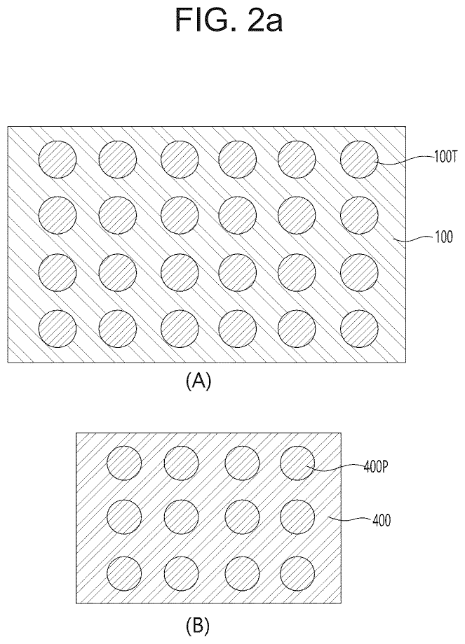

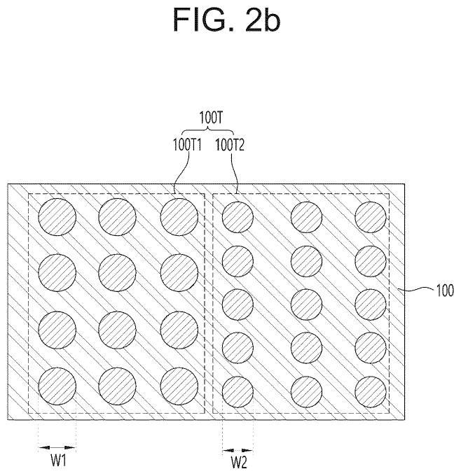

FIG. 1 is a cross-sectional view illustrating a semiconductor package according to a first embodiment, FIG. 2a is a plan view illustrating one example of a terminal pad of the semiconductor chip and a connection pad of a bridge chip of FIG. 1, and FIG. 2b is a plan view illustrating another example of a terminal pad of the semiconductor chip of FIG. 1.

Referring to FIG. 1, a semiconductor package 1000 according to a first embodiment includes a redistribution structure 300, a semiconductor chip 100 having a terminal pad 100T, a first molding member 200, a bridge chip 400 having a connection pad 400P, a conductive bump 500, and a second molding member 520.

The redistribution structure 300 is disposed between the semiconductor chip 100 and the bridge chip 400. The redistribution structure 300 electrically connects the semiconductor chip 100 and the bridge chip 400. For example, the redistribution structure 300 electrically connects the terminal pad 100T of the semiconductor chip 100 and the connection pad 400P of the bridge chip 400.

The redistribution structure 300 may include a redistribution insulating layer 310 and a redistribution line 320 to electrically connect the semiconductor chip 100 and the bridge chip 400. The redistribution line 320 refers to a signal line for transmitting an electrical signal, and may include a redistribution pattern 321 and a redistribution via 322 for this purpose.

The redistribution insulating layer 310 may be provided in a plurality of layers depending on a type and a number of semiconductor chips mounted on the redistribution structure 300. The redistribution insulating layer 310 may include a Photo Imageable Dielectric (PID) material. For example, the redistribution insulating layer 310 may include a photosensitive polyimide (PSPI). That is, the redistribution insulating layer 310 may include a photosensitive material capable of forming relatively fine wiring lines.

The redistribution line 320 includes a redistribution pattern 321 and a redistribution via 322. The redistribution pattern 321 and the redistribution via 322 of the redistribution line 320 may be disposed in the redistribution insulating layer 310. The redistribution pattern 321, which may also be referred to as a redistribution circuit, may be provided to extend along a horizontal direction on a surface of the redistribution insulating layer 310. The redistribution via 322 may extend along a vertical direction and pass through at least a portion of the redistribution insulating layer 310. The redistribution via 322 may electrically connect redistribution patterns 321 provided in different layers.

The redistribution pattern 321 and the redistribution via 322 may include metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or alloys thereof.

A width of the redistribution via 322 in the horizontal direction may vary in one direction. For example, the redistribution via 322 may have a slope in which the width in the horizontal direction increases along a direction from the semiconductor chip 100 toward the bridge chip 400. This may occur as a redistribution via 322 is formed by performing a sequential redistribution process while the semiconductor chip 100 is disposed.

The redistribution line 320 may include a lower pad (not shown). The lower pad of the redistribution line 320 may be disposed on a lower surface of the redistribution insulating layer 310. For example, the lower pad may be disposed on a lower surface of a redistribution pattern 321 disposed at a lowest side and may pass through at least a portion of the redistribution insulating layer 310. The lower pad may be referred to as an UBM layer and may electrically connect the redistribution structure 300 and the conductive bump 500.

The lower pad of the redistribution structure 300 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or an alloy thereof. The lower pad may further include a UBM seed layer (not shown). In this case, the UBM seed layer may be formed by performing a physical vapor deposition process, and the UBM layer of the lower pad may be formed by an electroplating process using the UBM seed layer.

In addition, in exemplary embodiments, the lower pad may include a wetting layer (such as a cover layer or a preliminary metal layer) having excellent wettability to improve connection reliability with the conductive bump 500. The wetting layer may be Au, Pd, Ni, Cu, Sn, and alloys thereof, or may be Ti, Cr, W, or Al.

A semiconductor chip 100 may be disposed on an upper portion of the redistribution structure 300, and a bridge chip 400 may be disposed on a lower portion of the redistribution structure 300. At this time, the semiconductor chip 100 and the bridge chip 400 may be respectively coupled to the upper and lower portions of the redistribution structure 300 using different coupling methods.

The semiconductor chip 100 may be directly connected to the redistribution line 320 of the redistribution structure 300. That is, the terminal pad 100T of the semiconductor chip 100 may be in direct contact with an uppermost redistribution line 320 among the redistribution lines 320 of the redistribution structure 300. Preferably, the terminal pad 100T of the semiconductor chip 100 may be directly connected to the redistribution via 322 disposed at an uppermost side of the redistribution structure 300.

The bridge chip 400 may be coupled to the redistribution structure 300 via a bonding member. For example, a conductive bump 500, which is a bonding member, may be disposed between the connection pad 400P of the bridge chip 400 and the redistribution structure 300. That is, the connection pad 400P of the bridge chip 400 may be electrically connected to the redistribution line 320 of the redistribution structure 300 via the conductive bump 500.

That is, the terminal pad 100T of the semiconductor chip 100 may be directly connected to the redistribution structure 300, and the connection pad 400P of the bridge chip 400 may be connected to the redistribution structure 300 via the conductive bump 500.

Through this, the embodiment can prevent warping occurring during a process of manufacturing process the semiconductor package 1000. Therefore, the embodiment can improve the manufacturing processability of the semiconductor package 1000, thereby improving product yield. That is, the embodiment can improve the electrical connection reliability between the semiconductor chip 100 and the redistribution structure 300, and the electrical connection reliability between the bridge chip 400 and the redistribution structure 300, which occur during the manufacturing process of the semiconductor package 1000. Furthermore, the embodiment can resolve the complexity of the manufacturing process of the semiconductor package 1000, thereby simplifying the manufacturing process and lowing the process difficulty. The reasons why such effects can be achieved are described in more detail below.

The semiconductor chip 100 can be mounted on the redistribution structure 300. The redistribution pattern 321 and the redistribution via 322 of the redistribution structure 300 can be electrically connected to the terminal pad 100T of the semiconductor chip 100.

The semiconductor chip 100 may include a plurality of individual devices of various types. For example, the plurality of individual devices may include microelectronic devices, complementary metal insulator semiconductor transistors (CMOS transistors), metal-oxide semiconductor field effect transistors (MOSFETs), system large scale integration (LSIs), optoelectronic devices such as CISs (CMOS imaging sensors), micro-electro-mechanical systems (MEMS), elastic wave filter devices, active devices, passive devices, etc., but are not limited thereto.

The semiconductor chip 100 may include a memory semiconductor chip. For example, the memory semiconductor chip may be a volatile memory semiconductor chip such as DRAM (Dynamic Random Access Memory) or SRAM (Static Random Access Memory), or a non-volatile memory semiconductor chip such as PRAM (Phase-change Random Access Memory), MRAM (Magneto-resistive Random Access Memory), FeRAM (Ferroelectric Random Access Memory), or RRAM (Resistive Random Access Memory), but is not limited thereto.

Preferably, the semiconductor chip 100 may include a logic chip. For example, the logic chip may be a Central Processor Unit), a DSP (Digital Signal Processor), a MPU (Micro Processor Unit), a GPU (Graphics Processor Unit), a MCU (Micro Processor Unit), an EPU (Encryption Processor Unit), or an AP (Application Processor), but is not limited thereto.

Preferably, a plurality of semiconductor chips 110, 120, and 130 may be mounted on the redistribution structure 210 while being spaced apart along the horizontal direction.

In an exemplary embodiment, the semiconductor chip 100 may include a first semiconductor chip 110, a second semiconductor chip 120, and a third semiconductor chip 130. At this time, the drawing illustrates that three semiconductor chips are disposed on the redistribution structure 300, but is not limited thereto. For example, two semiconductor chips 100 may be provided according to a product group of the semiconductor package 1000, or four or more semiconductor chips 100 may be provided.

In this case, each of the first semiconductor chip 110, the second semiconductor chip 120, and the third semiconductor chip 130 may include a digital chip, an analog chip, or a logic chip or memory chip, such as a system LSI (large scale integration).

In addition, the semiconductor package 1000 as described above may be a system-in-package (SIP) in which the first semiconductor chip 110, the second semiconductor chip 120, and the third semiconductor chip 130 disposed on a redistribution structure 300 are electrically connected to each other and operate as a single system.

Each of the first semiconductor chip 110, the second semiconductor chip 120, and the third semiconductor chip 130 may have an upper surface and a lower surface opposite to the upper surface. Each of the first semiconductor chip 110, the second semiconductor chip 120, and the third semiconductor chip 130 may have terminal pads 115, 125, and 135. The terminal pads 115, 125, and 135 may also be referred to as chip pads. The terminal pads 115, 125, and 135 of the first semiconductor chip 110, the second semiconductor chip 120, and the third semiconductor chip 130 can input and/or output signals between the first semiconductor chip 110/the second semiconductor chip 120/the third semiconductor chip 130 and the redistribution structure 300. The terminal pads 115, 125, and 135 of the first semiconductor chip 110, the second semiconductor chip 120, and the third semiconductor chip 130 are electrically connected to integrated circuits of the first semiconductor chip 110, the second semiconductor chip 120, and the third semiconductor chip 130, thereby allowing functions of the first semiconductor chip 110, the second semiconductor chip 120, and the third semiconductor chip 130 to be extended externally.

At this time, the terminal pads 115, 125, and 135 of the first semiconductor chip 110, the second semiconductor chip 120, and the third semiconductor chip 130 may be disposed to protrude from the first semiconductor chip 110, the second semiconductor chip 120, and the third semiconductor chip 130 at a certain height. The terminal pads 115, 125, and 135 may function to improve positional alignment with the redistribution structures 300, thereby improving the electrical connection reliability between the first semiconductor chip 110/the second semiconductor chip 120/the third semiconductor chip 130 and the redistribution structure 300.

A first molding member 200 may be disposed on the redistribution structure 300. The first molding member 200 may be disposed to cover at least a portion of the semiconductor chip 100. The first molding member 200 may be disposed to cover at least a portion of lower surface and side surfaces of the semiconductor chip 100.

A lower surface of the first molding member 200 may be at a same vertical level as a lower surface of the terminal pad 100T of the semiconductor chip 100. For example, the lower surface of the first molding member 200 and the terminal pad 100T of the semiconductor chip 100 may be positioned on a same plane.

Furthermore, an upper surface of the first molding member 200 may be at a same vertical level as an upper surface of the semiconductor chip 100. For example, the upper surface of the first molding member 200 and the upper surface of the semiconductor chip 100 may be positioned on a same plane.

The first molding member 200 may include a non-conductive material, thereby molding the semiconductor chip 100. The first molding member 200 may be provided to surround a side portion of the semiconductor chip 100 and reliably protect the semiconductor chip 100 from harmful external environments. The first molding member 200 may also be referred to as a protective member.

The first molding member 200 may include various oxide or polymer materials, but is not limited thereto. However, the first molding member 200 may be provided with an EMC (Epoxy Mold Compound) to improve processability while reducing the manufacturing cost of the semiconductor package 1000.

A vertical connection conductor 510 may be disposed under the redistribution structure 300. The vertical connection conductor 510 may be disposed on a lower surface of a lower pad of the redistribution structure 300 that is not connected to the bridge chip 400. The vertical connection conductor 510 may protrude downward from the vertical connection conductor 510 at a predetermined height. The vertical connection conductor 510 may have a pillar shape extending along the vertical direction within the second molding member 520. For example, the vertical connection conductor 510 may be provided to pass through the second molding member 520 along the vertical direction. A lower surface of the vertical connection conductor 510 may be at a same vertical level as the lower surface of the second molding member 520. The lower surface of the vertical connection conductor 510 may be positioned on a same plane as the lower surface of the second molding member 520. The vertical connection conductor 510 may electrically connect the redistribution structure 300 and a package substrate (described later). The vertical connection conductor 510 may include copper (Cu), aluminum (Al), solder, tin (Sn), zinc (Zn), lead (Pb), silver (Ag), gold (Au), palladium (Pd), or a combination thereof. In exemplary embodiments, the vertical connection conductor 510 may be a conductive post formed through a plating process and containing copper.

The conductive bump 500 may be disposed below the redistribution structure 300. The conductive bump 500 may be a bonding member for bonding the bridge chip 400 to the redistribution structure 300. That is, the connection pad 400P of the bridge chip 400 may be bonded to the redistribution structure 300 via the conductive bump 500. The conductive bump 500 electrically connects the connection pad 400P of the bridge chip 400 to the redistribution structure 300, thereby bonding and/or fixing the bridge chip 400. The conductive bump 500 may be formed using a solder ball, but is not limited thereto.

The bridge chip 400 may be coupled to the redistribution structure 300 via the conductive bump 500. The bridge chip 400 may be electrically connected to the semiconductor chip 100 via the redistribution structure 300. The bridge chip 400 may be provided to electrically connect a plurality of semiconductor chips.

A number of bridge chips 400 may be determined based on a number of semiconductor chips 100. For example, the bridge chip 400 may include a first bridge chip 410 and a second bridge chip 420. That is, when the number of semiconductor chips 100 is three, the number of bridge chips 400 may be two, but is not limited thereto.

The bridge chip 400 may function to electrically connect the semiconductor chips 100 disposed on the redistribution structure 300 along the horizontal direction. In one embodiment, the bridge chip 400 may be an inorganic bridge chip including an inorganic material. For example, the bridge chip 400 may be a silicon bridge chip including a silicon material. In this case, the bridge chip 400 may include a silicon substrate and a redistribution line.

In another embodiment, the bridge chip 400 may be an organic bridge chip including an organic material. For example, the bridge chip 400 may include an organic substrate in which the silicon substrate is redisposed with an organic material.

The bridge chip 400 may include a first bridge chip 410 and a second bridge chip 420.

A portion of the first bridge chip 410 may overlap the first semiconductor chip 110 along the vertical direction. Furthermore, another portion of the first bridge chip 410 may overlap the second semiconductor chip 120 along the vertical direction. The first bridge chip 410 may electrically connect the first semiconductor chip 110 and the second semiconductor chip 120.

A portion of the second bridge chip 420 may overlap the second semiconductor chip 120 along the vertical direction. Furthermore, another portion of the second bridge chip 420 may overlap the third semiconductor chip 130 along the vertical direction. The second bridge chip 420 may electrically connect the second semiconductor chip 120 and the third semiconductor chip 130.

In the embodiment, since the first semiconductor chip 110, the second semiconductor chip 120, and the third semiconductor chip 130 are electrically connected to each other through the first bridge chip 410 and the second bridge chip 420, electrical characteristics such as power integrity and signal integrity can be improved.

A second molding member 520 may be disposed under the redistribution structure 300. The second molding member 520 may be disposed to cover at least a portion of the bridge chip 400. The second molding member 520 may be provided to cover a side portion of the bridge chip 400. In addition, the second molding member 520 may be provided to cover a conductive bump 500 provided between the redistribution structure 300 and the bridge chip 400. In addition, the second molding member 520 may be provided to cover the vertical connection conductor 510.

A lower surface of the second molding member 520 may be at a same vertical level as a lower surface of the bridge chip 400. For example, the lower surface of the second molding member 520 and the lower surface of the bridge chip 400 may be positioned on a same plane. Furthermore, the lower surface of the second molding member 520 may be at a same vertical level as a lower surface of the vertical connection conductor 510. For example, the lower surface of the second molding member 520, the lower surface of the bridge chip 400, and the lower surface of the vertical connection conductor 510 may be positioned on a same plane.

The second molding member 520 may include a non-conductive material, thereby molding the bridge chip 400. The second molding member 520 may be provided to surround a side portion of the bridge chip 400 and reliably protect the bridge chip 400 from harmful external environments.

The second molding member 520 may include various oxide or polymer materials, but is not limited thereto. However, the second molding member 520 may be provided with EMC (Epoxy Mold Compound) to improve processability while reducing the manufacturing cost of the semiconductor package 1000.

An external pad 530 may be provided on the lower surface of the second molding member 520. The external pad 530 may be electrically connected to the vertical connection conductor 510. The external pad 530 may refer to a pad on which a conductive bump (to be described later) is provided for electrically connecting the semiconductor package 1000 described above and the package substrate (to be described later).

As described above, the semiconductor chip 100 may be disposed on the upper portion of the redistribution structure 300, and a bridge chip 400 may be disposed on the lower portion of the redistribution structure 300. In addition, a terminal pad 100T of the semiconductor chip 100 may be in direct contact with a redistribution line 320 disposed at an uppermost side among the redistribution lines 320 of the redistribution structure 300. Preferably, the terminal pad 100T of the semiconductor chip 100 may be directly connected to a redistribution via 322 disposed at an uppermost side of the redistribution structure 300. In addition, a conductive bump 500, which is a bonding member, may be disposed between the connection pad 400P of the bridge chip 400 and the redistribution structure 300. That is, the connection pad 400P of the bridge chip 400 can be electrically connected to the redistribution line 320 of the redistribution structure 300 via the conductive bump 500.

That is, the redistribution structure 300 can be manufactured by performing a redistribution process on the semiconductor chip 100. Accordingly, the redistribution via 322 of the redistribution structure 300 can have a structure that directly connects to the terminal pad 100T of the semiconductor chip 100. Furthermore, each redistribution via 322 provided in different layers can have a same slope, and in particular, can have a slope in which the width in the horizontal direction increases along the vertical direction from the semiconductor chip 100 toward the bridge chip 400.

Accordingly, the embodiment may prevent warpage occurring during a process of manufacturing the semiconductor package 1000. Accordingly, the embodiment may improve the manufacturing processability of the semiconductor package1000, thereby improving the product yield. In other words, the embodiment may improve the reliability of an electrical connection between the semiconductor chip 100 and the redistribution structure 300 and the reliability of the electrical connection between the bridge chip 400 and the redistribution structure 300, which occur during a process of manufacturing the semiconductor package 1000. Furthermore, the embodiment may solve the complexity of the manufacturing process of the semiconductor package 1000, thereby simplifying the manufacturing process and lowering the process difficulty. The reason why such an effect may be achieved will be described in more detail below.

That is, referring to (a) and (b) of FIG. 2a, the semiconductor chip 100 includes a terminal pad 100T, and the bridge chip 400 includes a connection pad 400P.

At this time, the number of terminal pads 100T of the semiconductor chip 100 is greater than the number of connection pads 400P of the bridge chip 400. For example, the semiconductor chip 100 may have about 60,000 to 150,000 terminal pads 100T. In contrast, the bridge chip 400 has 6,600 connection pads 400P. That is, the number of terminal pads 100T of the semiconductor chip 100 is more than 10 times greater than the number of connection pads 400P of the bridge chip 400.

Accordingly, when bonding the terminal pad 100T of the semiconductor chip 100 and the redistribution structure 300 using a conductive bump 500, significantly high-spec equipment is required to align the conductive bump 500 and the terminal pad 100T, which increases the process difficulty and may lower the product yield.

In contrast, in the embodiment, when a redistribution process is performed to form a redistribution structure 300 on the terminal pad 100T of the semiconductor chip 100, the process difficulty is lower than that of a flip-chip process using a conductive bump 500, and thus the manufacturing process can be simplified and the product yield can be improved. Furthermore, in the embodiment, a bridge chip 400 having a relatively small number of pads is bonded to the redistribution structure 300 through a flip-chip bonding process. In addition, the embodiment performs the redistribution process on a semiconductor chip 100 having a relatively large number of pads. Accordingly, the embodiment can improve the processability in the flip chip bonding process, thereby simplifying the manufacturing process, and further improving the product yield.

Furthermore, referring to FIG. 2b, the terminal pads 100T of the semiconductor chip 100 can be divided into a plurality of groups having different sizes. For example, the terminal pads 100T of the semiconductor chip 100 can include a first group 100T1 having a first size W1 and a second group 100T2 having a second size W2 smaller than the first size W1. The first group 100T1 of the terminal pads 100T can refer to pads that do not overlap with the bridge chip 400 in the vertical direction, or can refer to pads that are not electrically connected to the bridge chip 400. In addition, the second group 100T2 of terminal pads 100T can refer to pads that overlap with the bridge chip 400 along the vertical direction, or may refer to pads that are electrically connected to the bridge chip 400. That is, the semiconductor chip 100 is provided with terminal pads 100T of the second group 100T2 having a relatively small size, and accordingly, in order to electrically connect the terminal pads 100T of the second group 100T2 and the redistribution structure 300 through a flip chip bonding process, high-spec equipment may be required, which may result in a low product yield. Accordingly, the embodiment performs a redistribution process on a semiconductor chip 100 so that the semiconductor chip 100 and the redistribution structure 300 are directly connected to each other, and performs a flip-chip bonding process so that the bridge chip 400 and the redistribution structure 300 are electrically connected via a conductive bump 500. Therefore, the embodiment can improve the processability in the manufacturing process of a semiconductor package, thereby simplifying the manufacturing process, and further improving the product yield.

In addition, the number of semiconductor chips 100 may be greater than the number of bridge chips 400. Alternatively, a planar area of the semiconductor chip 100 may be greater than a planar area of the bridge chip 400. Alternatively, a thickness of the semiconductor chip 100 may be greater than a thickness of the bridge chip 400. Therefore, when the semiconductor chips 100 are preferentially disposed during a redistribution process in the semiconductor package manufacturing process, warpage can be improved compared to when the bridge chips 400 are preferentially disposed during the redistribution process. For example, the semiconductor chips 100 may function as reinforcing members during the redistribution process, thereby improving rigidity and process characteristics of the redistribution process. Therefore, the embodiment can allow the redistribution structure 300 to be more stably disposed on the semiconductor chips 100, thereby further improving the electrical and/or physical reliability of the semiconductor package.

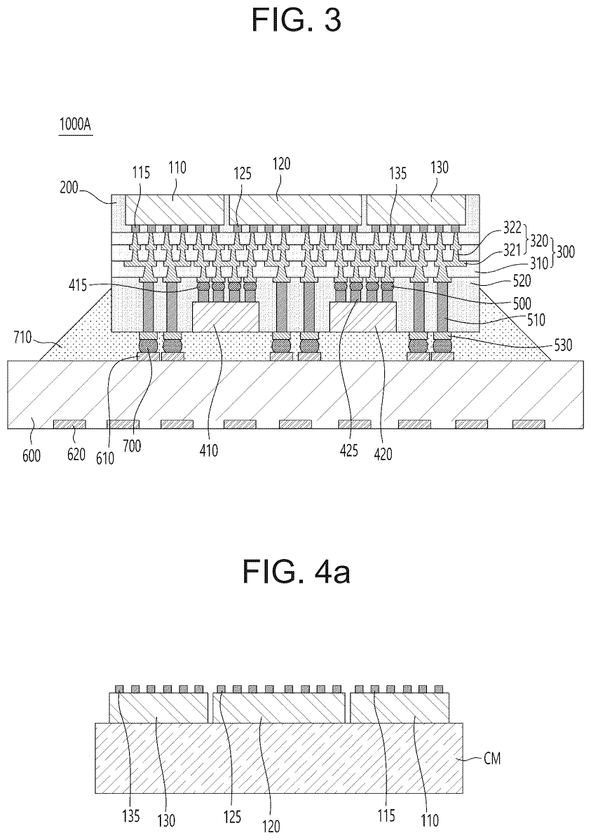

FIG. 3 is a cross-sectional view illustrating a semiconductor package according to a second embodiment.

Referring to FIG. 3, the semiconductor package 1000A of the second embodiment may have a structure in which a circuit board 600 is further coupled to the semiconductor package 1000 of FIG. 1.

The circuit board 600 may refer to a package substrate. The circuit board 600 may be formed based on a printed circuit board, a wafer substrate, a ceramic substrate, a glass substrate, etc. In exemplary embodiments, the circuit board 600 may be a multi-layer printed circuit board.

The circuit board 600 may include an upper pad 610 and a lower pad 620. The upper pad 610 may refer to a pad disposed at an uppermost side of the circuit board 600. For example, the circuit board 600 may refer to a pad facing an external pad 530 connected to the vertical connection conductor 510. A second conductive bump 700 may be disposed between the upper pad 610 and the external pad 530. The second conductive bump 700 may be disposed between the external pad 530 and the upper pad 610 to couple the circuit board 600 to the semiconductor package 1000 of FIG. 1.

The lower pad 620 of the circuit board 600 may refer to a pad disposed at a lowermost side of the circuit board 600. The lower pad 620 of the circuit board 600 may refer to a pad connected to a main board of an electronic device to which the semiconductor package 1000A of the second embodiment is applied.

An underfill member 710 is disposed between the second molding member 520 and the circuit board 600. The underfill member 710 may be filled in a region between the circuit board 600 and the second molding member 520. The underfill member 710 may be provided to surround a periphery of the second conductive bump 700. The underfill member 710 may mold a region between the circuit board 600 and the second molding member 520 so that the circuit board 600 and the redistribution structure 300 are integrated. One surface of the underfill member 710 may support the second molding member 520, and another surface of the underfill member 710 may support the circuit board 600.

The underfill member 710 may include an insulator. The underfill member 710 may be provided as an epoxy-based material. The underfill member 710 may be filled in a form of an underfill. The underfill may be filled to cover the upper surface of the circuit board 600 and the lower surface of the second molding member 520. In addition, the underfill member 710 may be filled to cover at least a portion of a side portion of the second molding member 520. For example, the underfill member 710 may be underfilled with an epoxy flux paste.

In addition, the underfill member 710 may use a thermally conductive underfill member (thermally conductive EMC, or thermally conductive reinforced resin) with a high thermal conductivity. The thermally conductive underfill member can prevent overheating of the semiconductor chip 100 and further enable more stable operation of the semiconductor chip 100 by allowing heat generated from the semiconductor chip 100 and/or the bridge chip 400 to be quickly dissipated to the outside.

The underfill member 710 can stabilize structural characteristics of the semiconductor package. In addition, the embodiment can mitigate shock transmitted to the semiconductor package 1000A due to external force. Furthermore, the underfill member 710 can absorb or externally dissipate heat emitted from the semiconductor package 1000A. Furthermore, the underfill member 710 can prevent alignment errors from occurring due to high heat or pressure generated during the manufacturing process when the external pad 530 and the upper pad 610 are disposed at a fine pitch.

A side surface of the underfill member 710 may be inclined. For example, the side surface of the underfill member 710 may have a tapered shape in which a width of the underfill member 710 in the horizontal direction increases along the vertical direction from the upper surface of the underfill member 710 toward the lower surface of the underfill member 710. For example, an outer width in the horizontal direction of the upper surface of the underfill member 710 may be smaller than an outer width in the horizontal direction of the lower surface of the underfill member 710.

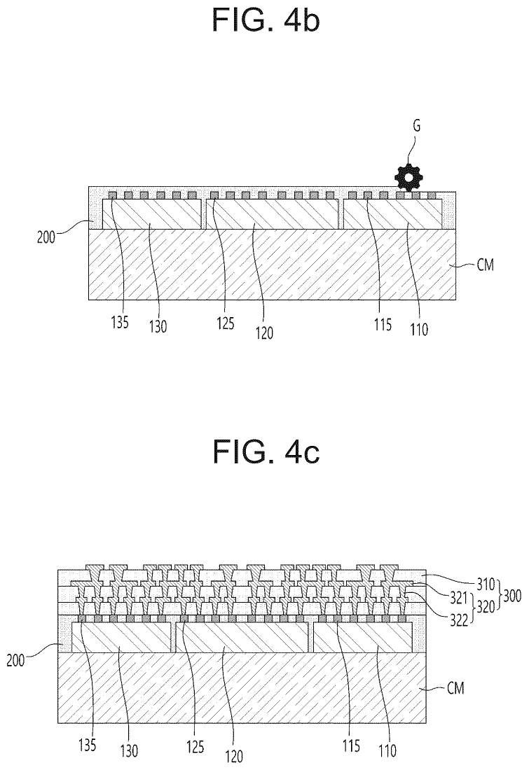

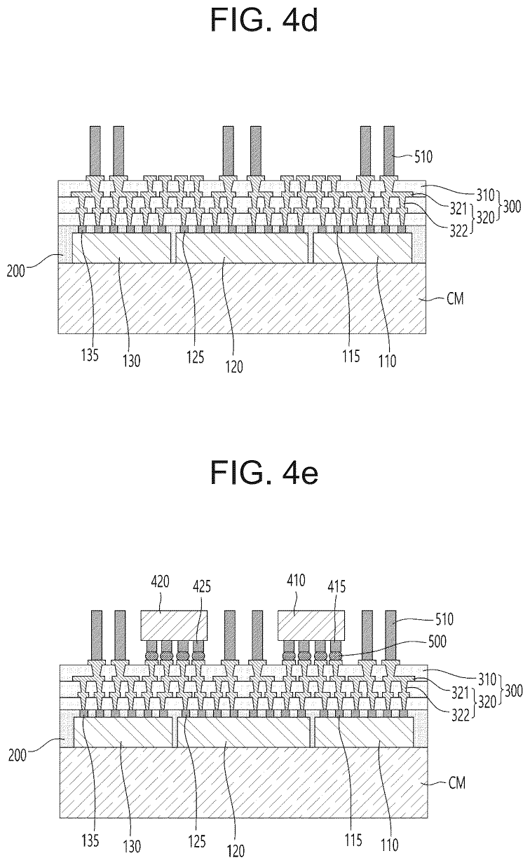

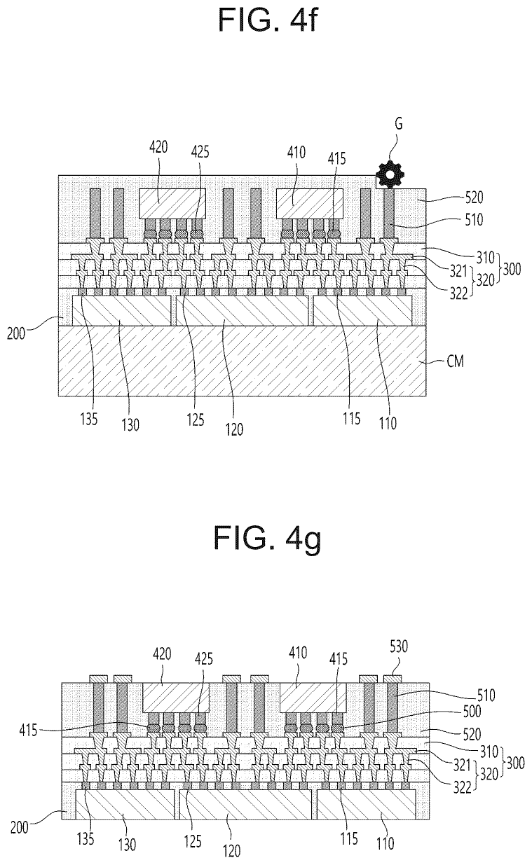

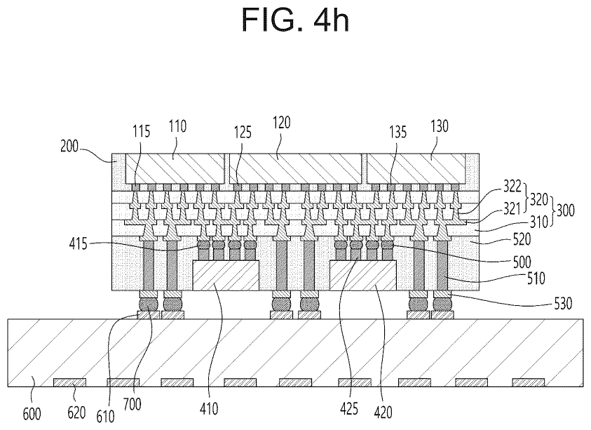

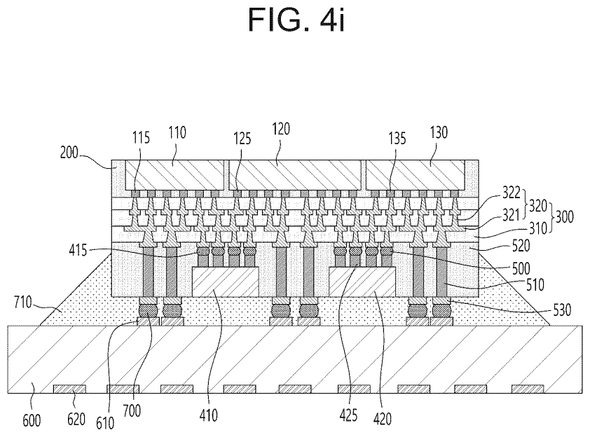

FIG. 4a to 4i are cross-sectional views illustrating a method of manufacturing the semiconductor package illustrated in FIG. 3 in order of processes.

Referring to FIG. 4a, the embodiment prepares a carrier member CM, which serves as a foundation for manufacturing the package 1000A. The carrier member CM may have various shapes depending on a product group of the semiconductor package.

The carrier member CM may have a flat plate shape. For example, in planar view, the carrier member CM may be circular. As another example, the carrier member CM may be a polygon, such as a rectangle, when viewed from a planar perspective. Specifically, the carrier member CM may be in a form of a wafer or a panel. The carrier member CM may be provided as a glass substrate, a ceramic substrate, or a plastic substrate.

Furthermore, a rigid member may be provided on at least one surface of the carrier member CM to offset warpage occurring during a process of manufacturing the semiconductor package.

Thereafter, the embodiment may proceed with a process of placing a semiconductor chip 100 on the carrier member CM. For example, an adhesive member (not shown) may be provided on an upper surface of the carrier member CM, and a process of attaching a first semiconductor chip 110, a second semiconductor chip 120, and a third semiconductor chip 130, which are spaced apart from each other in the horizontal direction, onto the carrier member CM may be performed using the adhesive member.

Next, referring to FIG. 4b, the embodiment may perform a process of forming a first molding member 200 for molding a semiconductor chip 100 on a carrier member CM. At this time, the first molding member 200 may be disposed to cover the terminal pad 100T of the semiconductor chip 100. Thereafter, the embodiment may perform a grinding process using a grinder (G), thereby exposing the terminal pad 100T of the semiconductor chip 100. For example, the embodiment may use the grinder (G) to position the upper surface of the first molding member 200 and the upper surface of the terminal pad 100T at a same vertical level.

Next, referring to FIG. 4c, the embodiment may perform a process of forming a redistribution structure 300 by performing a redistribution process on the semiconductor chip 100. In this case, the embodiment performs a redistribution process of the redistribution structure 300 on the semiconductor chip 100. Accordingly, the embodiment may easily control the warpage compared to performing the distribution process on the bridge chip 400, and further simplify the manufacturing process, thereby improving the product yield by improving the manufacturing process characteristics.

At this time, the redistribution process can be performed multiple times, and through this, the redistribution insulating layer 310, redistribution pattern 321, and redistribution via 322 of the redistribution structure 300 can be formed in multiple layers along the vertical direction.

Furthermore, in the embodiment, a redistribution via 322 closest to the semiconductor chip 100 in the redistribution structure 300 can be directly connected to the terminal pad 100T of the semiconductor chip 100. Furthermore, each redistribution via 322 provided on different layers may have a same slope, and in particular, may have a slope that increases in width as it moves away from the semiconductor chip 100.

Next, referring to FIG. 4d, the embodiment may perform a process of forming a vertical connection conductor 510 on the redistribution structure 300. The vertical connection conductor 510 may be formed through a plating process and may be disposed on the redistribution pattern 321 located at an uppermost side of the redistribution structure 300.

Next, referring to FIG. 4e, the embodiment may perform a flip-chip bonding process. In particular, the embodiment may perform a process of bonding a bridge chip 400 on the redistribution structure 300 using a conductive bump 500.

Next, referring to FIG. 4f, the embodiment may perform a process of forming a second molding member 520 that molds a vertical connection conductor 510, a bridge chip 400, and a conductive bump 500 on a redistribution structure 300. At this time, the second molding member 520 may perform a process of exposing an upper surface of the vertical connection conductor 510. That is, the embodiment may grind the second molding member 520 using a grinder (G) so that the upper surface of the second molding member 520 and the upper surface of the vertical connection conductor 510 are positioned on the same plane.

Next, referring to FIG. 4g, the embodiment may perform a process of forming an external pad 530 on the second molding member 520. The external pad 530 may be connected to the vertical connection conductor 510. Thereafter, the embodiment may proceed with a process of removing the carrier member CM.

Next, referring to FIG. 4h, the embodiment may proceed with a process of flipping the semiconductor package manufactured in FIG. 4g so that the external pad 530 faces downward. Thereafter, the embodiment may proceed with a process of bonding the circuit board 600 to the redistribution structure 300 using the second conductive bump 700. In particular, the embodiment may proceed with a process of electrically connecting the circuit board 600 to the external pad 530 by placing the second conductive bump 700 between the upper pad 610 of the circuit board 600.

Next, referring to FIG. 4i, the embodiment may proceed with an underfill process of forming an underfill member 710 in a region between the second molding member 520 and the circuit board 600. The underfill member 710 may cover the external pad 530, the upper pad 610, and the second conductive bump 700, while also covering at least a portion of a side portion of the second molding member 520.

Hereinafter, a semiconductor package according to another embodiment will be described.

Hereinafter, the same contents as those previously described in the first and second embodiments will be briefly described or omitted. Furthermore, in the semiconductor package of the following embodiment, same reference numerals are assigned to a configuration substantially the same as and/or similar to that of the semiconductor package of the previous embodiment.

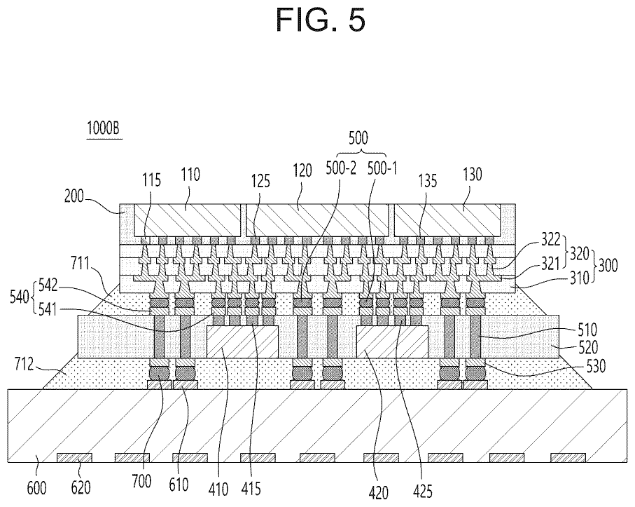

FIG. 5 is a cross-sectional view illustrating a semiconductor package according to a third embodiment.

Referring to FIG. 5, a semiconductor package 1000B according to a third embodiment may include a redistribution structure 300, a semiconductor chip 100, a first molding member 200, a second molding member 520, a vertical connection conductor 510, a bridge chip 400, a first conductive bump 500, a second conductive bump 700, a first underfill member 711, and a second underfill member 712.

At this time, the semiconductor package 1000B of the third embodiment may have a structure in which a first package including a redistribution structure 300 on which a semiconductor chip 100 is mounted, and a second package including a bridge chip 400 are separated from each other and connected to each other through the first conductive bump 500.

In particular, the second package may have a structure in which the vertical connection conductor 510 is separated from the redistribution structure 300 together with the bridge chip 400 and the second molding member 520, and the first conductive bump 500 may be further disposed between the vertical connection conductor 510 and the redistribution structure 300.

That is, an upper external pad 540 is connected to the upper surface of the vertical connection conductor 510 and the connection pad 400P of the bridge chip 400, and disposed on the second molding member 520. At this time, the upper external pad 540 includes a first upper external pad 541 disposed on the connection pad 400P of the bridge chip 400 and a second upper external pad 542 disposed on the vertical connection conductor 510.

In addition, the first conductive bump 500 includes a first bump 500-1 disposed between the first upper external pad 541 and the redistribution structure 300, and a second bump 500-2 disposed between the second upper external pad 542 and the redistribution structure 300.

That is, in the first embodiment, the bridge chip 400 is coupled in a state in which the vertical connection conductor 510 is disposed on the redistribution structure 300. In contrast, in the third embodiment, the vertical connection conductor 510 is coupled to the redistribution structure 300 in a state of being packaged with the bridge chip 400 through the second molding member 520.

Accordingly, the third embodiment may include a first bump 500-1 disposed between the first upper external pad 541 and the redistribution structure 300 and a second bump 500-2 disposed between the second upper external pad 542 and the redistribution structure 300, and accordingly the first package and the second package may be coupled to each other.

Furthermore, the underfill member may include a first underfill member 711 and a second underfill member 712. The first underfill member 711 may fill a region between the first package including the semiconductor chip 100 and the redistribution structure 300 and the second package including the bridge chip 400. The first underfill member 711 may be disposed to surround a side portion of the first conductive bump 500. In addition, the first underfill member 711 may be disposed to cover at least a portion of the side portion of the redistribution structure 300.

That is, in the semiconductor package of the third embodiment, a width of the second molding member 520 in the horizontal direction may be greater than a width of the first molding member 200 in the horizontal direction or a width of the redistribution structure 300 in the horizontal direction. Accordingly, filling of the region between the redistribution structure 300 and the bridge chip 400 may be performed on the second molding member 520, and accordingly, the first underfill member 710 may have a slope such that the width in the horizontal direction decreases as it approaches the semiconductor chip 100.

In addition, the second underfill member 712 may be disposed between the second molding member 520 and the circuit board 600 and may fill the region therebetween. That is, the second underfill member 712 may be disposed to surround the second conductive bump 700. The second underfill member 712 may correspond to the underfill member 710 of the semiconductor package of the second embodiment.

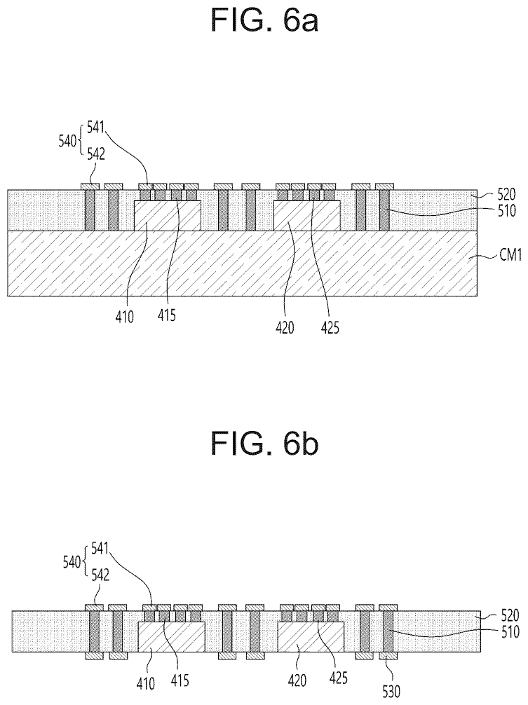

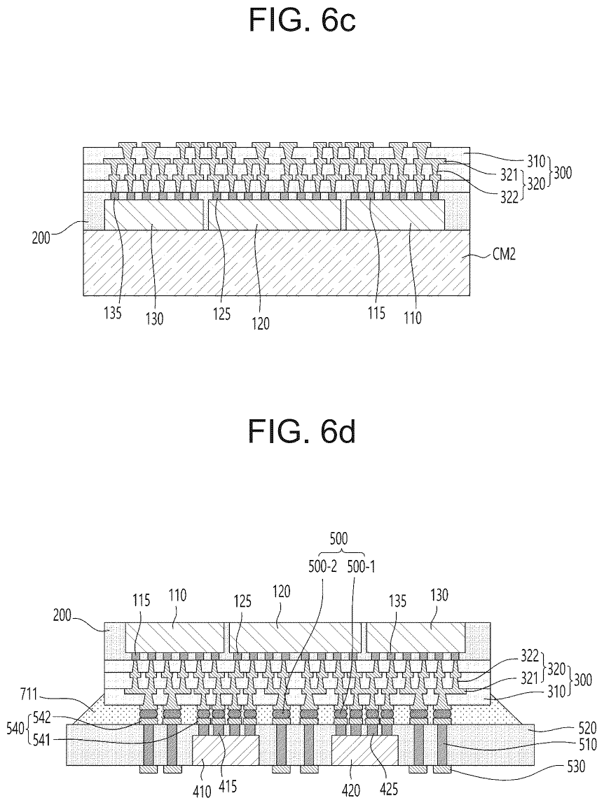

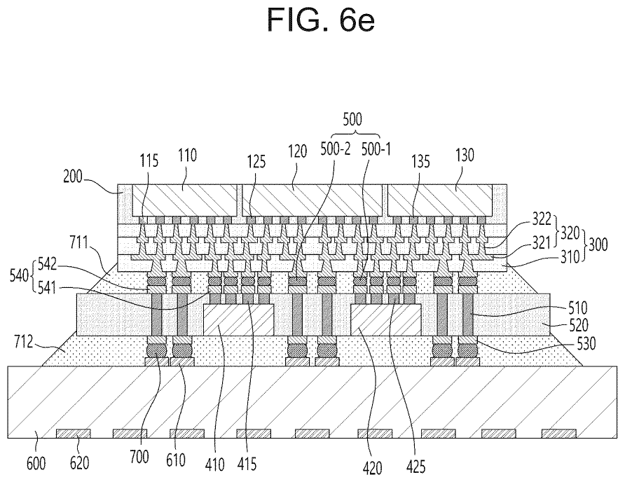

FIG. 6a to 6e are cross-sectional views illustrating a method of manufacturing the semiconductor package illustrated in FIG. 5 in order of processes.

Referring to FIG. 6a, the embodiment prepares a first carrier member CM1. At this time, a metal layer (not shown) may be provided on the first carrier member CM1. A plating process may be performed on the metal layer of the first carrier member CM1 as a seed layer. Through this, the embodiment may perform a process of forming a vertical connection conductor 510 on the first carrier member CM1.

Thereafter, the embodiment may proceed with a process of attaching bridge chips 400 spaced apart along the horizontal direction on the first carrier member CM1. For example, the embodiment may proceed with a process of forming an adhesive member on the metal layer of the first carrier member CM1 and attaching the bridge chips 400 between a plurality of vertical connection conductors 510 using the adhesive member.

Thereafter, the embodiment may proceed with a process of forming a second molding member 520 that molds the vertical connection conductor 510 and the bridge chip 400. At this time, the upper surface of the second molding member 520 may be positioned on the same plane as the upper surface of the connection pad 400P of the bridge chip 400 and the upper surface of the vertical connection conductor 510 through a grinding process.

Thereafter, the embodiment may proceed with a process of forming an upper external pad 540 on the vertical connection conductor 510 and the connection pad 400P of the bridge chip 400.

Referring to FIG. 6b, the embodiment may proceed with a process of removing the first carrier member CM1. Furthermore, the embodiment may proceed with a process of forming a lower external pad 530 on the lower surface of the vertical connection conductor 510. Through this, the manufacturing of a package in which the bridge chip 400 and the vertical connection conductor 510 are molded with the first molding member 200 is completed.

Next, referring to FIG. 6c, the embodiment prepares a second carrier member CM2. Thereafter, the embodiment may proceed with a process of attaching the semiconductor chip 100 on the second carrier member CM2, a process of forming the first molding member 200, and a process of forming the redistribution structure 300. This has already been explained in FIGS. 4a to 4c, so a detailed description thereof will be omitted.

Thereafter, the embodiment removes the second carrier member CM2. Accordingly, the manufacturing of a package including a semiconductor chip 100 molded with a first molding member 200 and a redistribution structure 300 disposed under the first molding member 200 is completed.

Next, referring to FIG. 6d, the embodiment may proceed with a process of coupling the first and second packages manufactured in FIGS. 6a to 6c. To this end, the embodiment may proceed with a process of placing a first conductive bump 500 on the upper external pad 540. Thereafter, the embodiment may proceed with a process of coupling the package including the semiconductor chip 100 and the redistribution structure 300 using the first conductive bump 500.

Thereafter, the embodiment may proceed with a process of filling a region where the first conductive bump 500 is disposed with a first underfill member 710.

Next, referring to FIG. 6e, the embodiment may proceed with a process of bonding the circuit board 600 to the lower external pad 530 using the second conductive bump 700. Thereafter, the embodiment may proceed with a process of forming a second underfill member 712 in a region where the second conductive bump 700 is disposed.

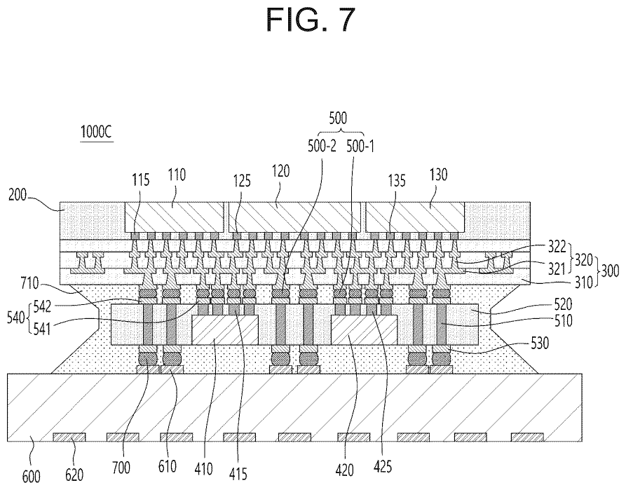

FIG. 7 is a cross-sectional view illustrating a semiconductor package according to a fourth embodiment.

Referring to FIG. 7, a structure of the underfill member 710 in the semiconductor package 1000C according to the fourth embodiment may differ from that of the semiconductor package 1000B according to the third embodiment of FIG. 6.

That is, in the semiconductor package 1000B according to the third embodiment of FIG. 6, the width of the first molding member 200 in the horizontal direction or the width of the redistribution structure 300 in the horizontal direction is smaller than the width of the second molding member 520 in the horizontal direction, and thus, the filling of the region between the redistribution structure 300 and the second molding member 520 proceeds on the upper surface of the second molding member 520.

In contrast, in the semiconductor package 1000C according to the fourth embodiment of FIG. 7, a width of the first molding member 200 in the horizontal direction or a width of the redistribution structure 300 in the horizontal direction is greater than a width of the second molding member 520 in the horizontal direction.

Accordingly, filling of the region between the redistribution structure 300 and the second molding member 520 can be performed on the lower surface of the redistribution structure 300.

Therefore, the underfill member 710 may have a slope in which the width in the horizontal direction decreases from the redistribution structure 300 toward the first molding member 200.

At this time, the underfill member 710 includes a first portion formed by performing the process on the lower surface of the redistribution structure 300 and a second portion formed by performing the process on the upper surface of the circuit board 600. Furthermore, when performing the underfill process to form the first portion and the second portion, respectively, the first portion and the second portion may be connected to each other, thereby forming a single underfill member 710.

Accordingly, the underfill member 710 can fill a region between the first molding member 200 and the redistribution structure 300, and a region between the first molding member 200 and the circuit board 600, respectively. Furthermore, the underfill member 710 can be provided to completely surround a side portion of the first molding member 200.

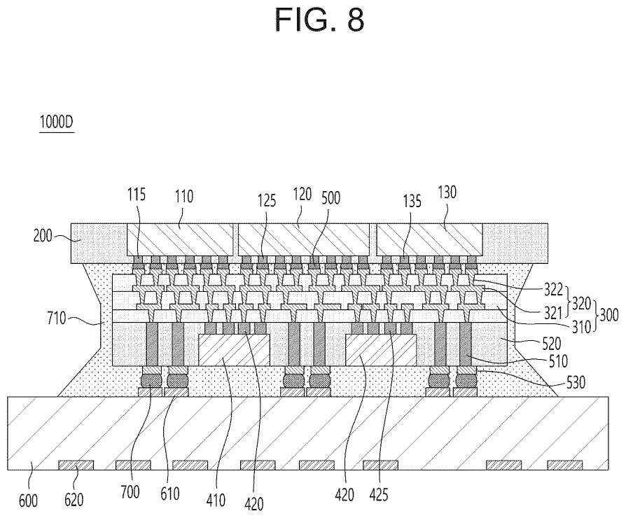

FIG. 8 is a cross-sectional view illustrating a semiconductor package according to a fifth embodiment.

Referring to FIG. 8, the semiconductor package 1000D according to the fifth embodiment may differ from the semiconductor package 1000B according to the fourth embodiment of FIG. 7 in that the redistribution process for forming the redistribution structure 300 is performed on the bridge chip 400 rather than the semiconductor chip 100.

That is, the second molding member 520 is provided to mold the bridge chip 400. At this time, the vertical connection conductor 510 may be provided to penetrate the second molding member 520 at a position spaced apart from the bridge chip 400.

In addition, the redistribution structure 300 may be disposed on the vertical connection conductor 510 and the connection pad 400P of the bridge chip 400. For example, the redistribution via 322 of the redistribution structure 300 may be in direct contact with the upper surface of the vertical connection conductor 510 and the connection pad 400P of the bridge chip 400

In addition, a first conductive bump 500 may be disposed on the redistribution structure 300. In addition, the first conductive bump 500 may be disposed between the redistribution structure 300 and the terminal pad 100T of the semiconductor chip 100. That is, the first conductive bump 500 can couple the semiconductor chip 100 to the redistribution structure 300. In addition, the first molding member 200 can be provided to surround a periphery of the semiconductor chip 100.

That is, the semiconductor package 1000D of FIG. 8 can proceed with a process of forming the redistribution structure 300 of FIG. 6c on the vertical connection conductor 510 and the connection pad 400P of the bridge chip 400 without performing the process of forming the upper external pad 540 of FIG. 6a.

Furthermore, the semiconductor package 1000D of FIG. 8 can proceed with a process of removing the second carrier member CM2 in a state in which the first molding member 200 for molding the semiconductor chip 100 is formed, without performing the process of forming the redistribution structure 300 of FIG. 6c.

In addition, the package manufactured in this way may be coupled with each other using the first conductive bump 500 to manufacture the semiconductor package 1000D of FIG. 8.

Through this, the underfill member 710 can be provided by completely filling the region between the semiconductor chip 100 molded with the first molding member 200 and the circuit board 600. For example, the underfill member 710 can be provided by completely filling the first conductive bump 500, the redistribution structure 300, the second molding member 520, and the second conductive bump 700.

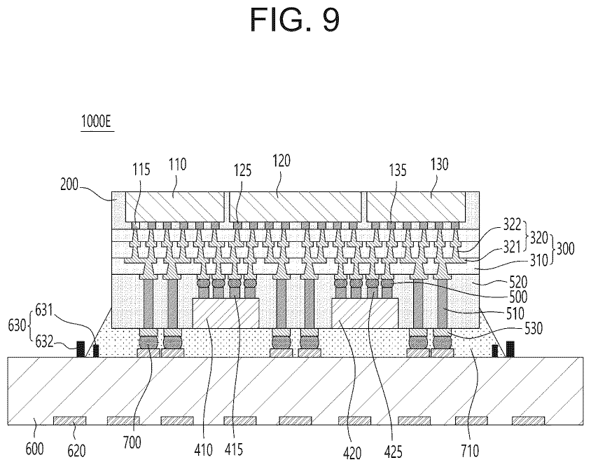

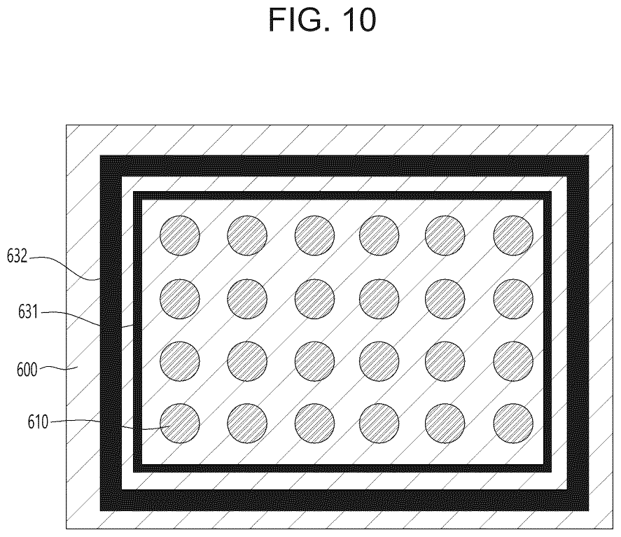

FIG. 9 is a cross-sectional view illustrating a semiconductor package according to a sixth embodiment, and FIG. 10 is a top view of the circuit board of FIG. 9.

Referring to FIGS. 9 and 10, the semiconductor package 1000E according to the sixth embodiment may include the semiconductor package 1000A according to the second embodiment illustrated in FIG. 3 and may further include a dam part 630.

The dam part 630 may be provided on the upper surface of the circuit board 600. The dam part 630 may include a metal material. In an exemplary embodiment, the dam part 630 may be provided with a same metal material as a metal material of the upper pad 610 provided on the upper surface of the circuit board 600. That is, the dam part 630 may be formed together with the upper pad 610 during the process of forming the upper pad 610 of the circuit board 600.

The dam part 630 may control the flowability of the underfill material 710, thereby minimizing bleed out of the underfill material 710. For example, the dam part 630 may control a degree of spreading in a horizontal direction of the underfill material 710, thereby ensuring that the underfill material 710 is provided only in a designated target region.

The dam part 630 may be provided in multiple lines on the upper surface of the circuit board 600. For example, the dam part 630 may include a first portion 631 surrounding an upper pad 610 provided on the upper surface of the circuit board 600, and a second portion 632 surrounding the first portion 631 at a position spaced apart from the first portion 631.

The first portion 631 and the second portion 632 of the dam part 630 may have different widths in the horizontal direction or different heights in the vertical direction.

For example, the first portion 631 of the dam part 630 may be provided with a first width along a circumferential direction of the upper pad 610, and the second portion 632 may have a second width different from the first width along a circumferential direction of the first portion 631 of the dam part 630. At this time, the first width of the first portion 631 of the dam part 630 is shown in the drawing to be smaller than the second width of the second portion 632 of the dam part 630, but the embodiment is not limited thereto. That is, the widths of the first portion 631 and the second portion 632 of the dam part 630 in the horizontal direction can be adjusted in consideration of the degree of spreading in the horizontal direction of the underfill member 710 and an area in which the underfill member 710 is disposed. Accordingly, it is also possible to make the second portion 632 of the dam part 630 have a wider width than the first portion 631 of the dam part 630.

In addition, in the drawing, the first portion 631 and the second portion 632 of the dam part 630 are shown to be provided in a closed loop shape on the upper surface of the circuit board 600, but the embodiment is not limited thereto. For example, at least one of the first portion 631 and the second portion 632 of the dam part 630 may have an open-loop shape in which at least a portion is cut off. This may be determined by considering a viscosity of a material of the underfill member 710, the area of the region where the underfill member 710 is disposed, etc.

In addition, a height of the first portion 631 of the dam part 630 may be different from a height of the second portion 632. For example, the second portion 632 of the dam part 630 may be provided further outward than the first portion 631 of the dam part 630. Accordingly, the height or thickness of the second portion 632 of the dam part 630 may be greater than the height or thickness of the first portion 631. Accordingly, the first portion 631 of the dam part 630 may preferentially prevent the underfill material 710 from spreading out, and the second portion 632 may additionally control the spread of the underfill material 710 so that the underfill material 710 is disposed only in the designated region.

Therefore, the embodiment can control the degree of spreading of the underfill material 710 using the dam part 630, thereby ensuring that the underfill material 710 is stably disposed only in a designated region. This allows the embodiment to more stably protect the semiconductor package, thereby further improving physical and/or electrical reliability. In addition, the embodiment may allow the underfill member 710 to be stably formed even with a small amount by controlling the degree of spreading of the underfill member 710 in the horizontal direction. Accordingly, the embodiment may reduce the manufacturing cost of the semiconductor package.

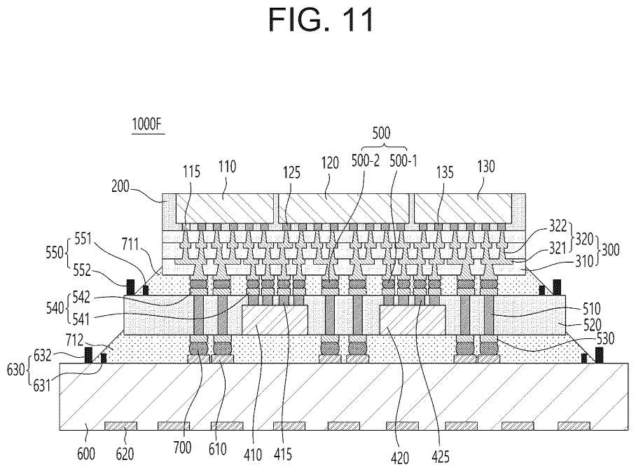

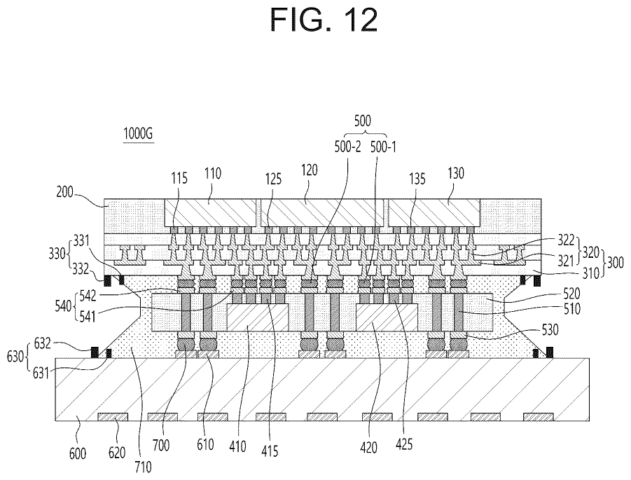

FIG. 11 is a cross-sectional view illustrating a semiconductor package according to a seventh embodiment, and FIG. 12 is a cross-sectional view illustrating a semiconductor package according to an eighth embodiment.

Referring to FIG. 11, the semiconductor package 1000G according to the seventh embodiment may include a plurality of dam parts disposed at different locations.

That is, the semiconductor package 1000F according to the seventh embodiment may include the semiconductor package 1000B according to the third embodiment illustrated in FIG. 5, and may further include a first dam part 630 and a second dam part 550.

The first dam part 630 is a dam part provided on the upper surface of the circuit board 600 described in FIG. 10, and may include the first portion 631 and the second portion 632.

Furthermore, the second dam part 550 may be further provided on the upper surface of the second molding member 520. The second dam part 550 may be provided on the upper surface of the second molding member 520 to surround the periphery of the upper external pad 540. The second dam part 550 may include a first portion 551 provided to surround the periphery of the upper external pad 540, and a second portion 552 provided to surround the periphery of the first portion 551. The first portion 551 and the second portion 552 of the second dam part 550 may be formed together with the upper external pad 540 in the process of forming the upper external pad 540.

At this time, the first dam part 630 may be provided to control the degree of spreading of the underfill member 712 provided on the upper surface of the circuit board 600. In addition, the second dam part 550 may be provided to control the degree of spreading of the underfill member 711 provided on the upper surface of the second molding member 520. Therefore, the embodiment makes it possible to stably form each of the underfill members 711 and 712 provided at different positions.

Also, referring to FIG. 12, the semiconductor package 1000F according to the eighth embodiment may include a plurality of dam parts positioned at different positions.

That is, the semiconductor package 1000G according to the eighth embodiment may include the semiconductor package 1000C according to the fourth embodiment illustrated in FIG. 7, and may further include a first dam part 630 and a second dam part 330.

The first dam part 630 is a dam part disposed on the upper surface of the circuit board 600 described in FIG. 10, and may include a first portion 631 and a second portion 632.

In addition, the second dam part 330 may be disposed on the lower surface of the redistribution structure 300. The second dam part 330 may be disposed on the lower surface of the redistribution structure 300 to surround the lower pad. The second dam part 330 may include a first portion 331 that is provided to surround the lower pad of the redistribution structure 300, and a second portion 332 that is provided to surround the first portion 331. The first portion 331 and the second portion 332 of the second dam part 330 may be formed together with the upper and lower pads in the process of forming the lower pad.

In this case, the first dam part 630 may be provided to improve process characteristics of the underfill process performed on the upper surface of the circuit board 600, and the second dam part 3430 may be provided to improve process characteristics of the underfill process performed on the lower surface of the distribution structure 300. Accordingly, the embodiment may allow the underfill member 710 to be more stably disposed between the distribution structure 300 and the circuit board 600 by using the first dam part 630 and the second dam part 330. It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

1. A semiconductor package comprising:
a bridge chip including a connection pad;
a redistribution structure disposed on the bridge chip and including a redistribution line connected to the connection pad of the bridge chip; and
a first semiconductor chip and a second semiconductor chip disposed on the redistribution structure and spaced apart from each other along a horizontal direction and including a terminal pad connected to the redistribution line,
wherein one of the connection pad and the terminal pad is positioned on a same plane as the redistribution structure,
wherein other pad of the connection pad and the terminal pad is positioned on a different plane from the redistribution structure, and
wherein a first conductive bump is disposed between the other pad and the redistribution structure.

2. The semiconductor package of claim 1, further comprising:
a first molding member molding the first semiconductor chip and the second semiconductor chip;
a second molding member molding the bridge chip; and
a vertical connection conductor passing through the second molding member along a vertical direction,
wherein the redistribution line of the redistribution structure includes a plurality of redistribution patterns disposed at different vertical levels, and a plurality of redistribution vias disposed between the plurality of redistribution patterns and disposed at different vertical levels,
wherein the terminal pad is in direct contact with a redistribution via that is most closely disposed among the plurality of redistribution vias, and
wherein a width of each of the plurality of redistribution vias in a horizonal direction increases from the first semiconductor chip or the second semiconductor chip toward the bridge chip.

3. The semiconductor package of claim 2, wherein the vertical connection conductor is in direct contact with the redistribution line of the redistribution structure and is electrically connected to the redistribution line, and
wherein at least a portion of the vertical connection conductor overlaps the first conductive bump along the horizontal direction.

4. The semiconductor package of claim 2, further comprising:
a circuit board including an upper pad and a lower pad;
a second conductive bump disposed between the upper pad of the circuit board and the vertical connection conductor; and
a first underfill member disposed on the circuit board and surrounding the second conductive bump.

5. The semiconductor package of claim 4, wherein the circuit board further includes a first dam part disposed to surround the upper pad, and
wherein the first dam part includes a first portion disposed to surround the upper pad, and a second portion spaced from the first portion and surrounding the first portion.

6. The semiconductor package of claim 5, wherein a width in the horizontal direction or a thickness in the vertical direction of the first portion of the first dam part is different from at least one of a width in the horizontal direction or a thickness in the vertical direction of the second portion of the first dam part.

7. The semiconductor package of claim 2, wherein the first conductive bump includes:
a first bump disposed between the connection pad and the redistribution structure; and
a second bump disposed between the vertical connection conductor and the redistribution structure,
wherein a second underfill member is further disposed on the second molding member and surrounds the first bump and the second bump.

8. The semiconductor package of claim 7, further comprising:
a second dam part disposed on an upper surface of the second molding member and surrounding the first conductive bump.

9. The semiconductor package of claim 7, further comprising:
a second dam part disposed on a lower surface of the redistribution structure and surrounding the first conductive bump.

10. The semiconductor package of claim 7, wherein the second underfill member entirely covers an upper surface of the first molding member, a lower surface of the first molding member, and a side surface of the first molding member.

11. The semiconductor package of claim 10, wherein the second underfill member includes a first region whose width in the horizontal direction decreases and a second region whose width in the horizontal direction increases along a vertical direction from the first molding member toward the second molding member.

12. The semiconductor package of claim 1, further comprising:
a first molding member for molding the first semiconductor chip and the second semiconductor chip;
a second molding member for molding the bridge chip; and
a vertical connection conductor passing through the second molding member along a vertical direction,
wherein the redistribution line of the redistribution structure includes a plurality of redistribution patterns disposed at different vertical levels, and a plurality of redistribution vias disposed between the plurality of redistribution patterns and disposed at different vertical levels,
wherein the connection pad is in direct contact with a redistribution via that is most closely disposed among the plurality of redistribution vias,
wherein a width of each of the plurality of redistribution vias in a horizontal direction decrease from the first semiconductor chip or the second semiconductor chip toward the bridge chip,
wherein a width of the first molding member in the horizontal direction is greater than a width of each of the redistribution structure and the second molding member in the horizontal direction, and
wherein an underfill member is disposed to entirely surround a lower surface of the first molding member, an upper surface of the redistribution structure, a side surface of the redistribution structure, a side surface of the second molding member, and a lower surface of the second molding member.
